(19) United States
(12) Patent Application Publication
(10) Pub. No.: US 2025/0160221 A1
(43) Pub. Date: May 15, 2025

(54) METHOD OF MANUFACTURING A SUPERCONDUCTIVE INTEGRATED CIRCUIT

(71) Applicant: Infineon Technologies AG, Neubiberg (DE)

(72) Inventors: Wolfgang RABERG, Sauerlach (DE); Michael KIRSCH, Regensburg (DE); Jash BANKER, Unterhaching (DE); Jochen BRAUMÜLLER, Holzkirchen (DE); Nicolas ARLT, München (DE)

(21) Appl. No.: 18/933,010

(22) Filed: Oct. 31, 2024

(30) Foreign Application Priority Data
Nov. 9, 2023 (DE) 102023131059.3

(51) Int. Cl. H10N 60/01; H10N 60/12; H10N 69/00

(52) U.S. Cl. CPC H10N 60/0912; H10N 60/12; H10N 69/00

(57) ABSTRACT

A method of manufacturing a superconductive integrated circuit on a substrate includes forming a first superconductive layer of a superconductive material over the substrate. A Josephson junction (JJ) layer stack including a JJ barrier layer is formed over the first superconductive layer. The JJ layer stack is structured to form a JJ structure. The first superconductive layer is structured to form a structured first superconductive layer. A dielectric cover layer is formed over the JJ structure. The dielectric cover layer is structured a first time to expose an upper side of the JJ structure. A second superconductive layer of a superconductive material is formed over the dielectric cover layer. The second superconductive layer is structured to form a structured second superconductive layer.

### CROSS-REFERENCE TO RELATED APPLICATION

This application claims priority to Germany Patent Application No. 102023131059.3 filed on Nov. 9, 2023, the content of which is incorporated by reference herein in its entirety.

### TECHNICAL FIELD

This disclosure relates generally to the field of superconductive integrated circuits, and in particular to integration concepts for Josephson junctions on substrates.

### BACKGROUND

Electronic devices including a superconductive integrated circuit are used in the art in various technical fields. For example, quantum computing devices operating one or a plurality of superconducting quantum bits (qubits) rely on superconductive integrated circuits.

Quantum computing is a method promising to solve specific tasks significantly faster than conventional computers. One approach to realize circuits for such a computer is to create qubits including superconducting Josephson junctions and capacitors.

Superconductive integrated circuits including Josephson junctions are also used in single flux quantum (SFQ) devices and traveling-wave parametric amplifiers (TWPAs).

Today, most manufacturing methods are using processes like shadow mask evaporation and lift off to realize these circuits. Those processes suffer from reproducibility issues and defect density and typically do not allow significant scaling both in dimension and stacking.

### SUMMARY

According to an aspect of the disclosure, a method of manufacturing a superconductive integrated circuit on a substrate includes forming a first superconductive layer of a superconductive material over the substrate. A Josephson junction (JJ) layer stack including a JJ barrier layer is formed over the first superconductive layer. The JJ layer stack is structured to form a JJ structure. The first superconductive layer is structured to form a structured first superconductive layer. A dielectric cover layer is formed over the JJ structure. The dielectric cover layer is structured a first time to expose an upper side of the JJ structure. A second superconductive layer of a superconductive material is formed over the dielectric cover layer. The second superconductive layer is structured to form a structured second superconductive layer.

### BRIEF DESCRIPTION OF THE DRAWINGS

The elements of the drawings are not necessarily to scale relative to each other. Like reference numerals designate corresponding similar parts. The features of the various illustrated implementations can be combined unless they exclude each other and/or can be selectively omitted if not described to be necessarily required. Implementations are depicted in the drawings and are exemplarily detailed in the description which follows.

FIGS. 1 to 5 are schematic cross-sectional views illustrating stages of a method of manufacturing a superconductive integrated circuit on a substrate, in accordance with a first implementation.

FIGS. 6 to 8 are schematic cross-sectional views illustrating stages of a method of manufacturing a superconductive integrated circuit on a substrate, in accordance with a second implementation.

FIGS. 9 to 18 are schematic cross-sectional views illustrating stages of a method of manufacturing a superconductive integrated circuit on a substrate, in accordance with a third implementation.

### DETAILED DESCRIPTION

The words “over” or “beneath” or similar words with regard to a part, element or material layer formed or located or disposed or arranged or placed “over” or “beneath” a surface may be used herein to mean that the part, element or material layer be located (e.g., placed, formed, arranged, disposed, etc.) “directly on” or “directly under”, e.g., in direct contact with, the implied surface. The word “over” or “beneath” or similar words used with regard to a part, element or material layer formed or located or disposed or arranged or placed “over” or “beneath” a surface may, however, either be used herein to mean that the part, element or material layer be located (e.g., placed, formed, arranged, deposited, etc.) “indirectly on” or “indirectly under” the implied surface, with one or more additional parts, elements or layers being arranged between the implied surface and the part, element or material layer.

The following description relates by way of example to methods of manufacturing a superconductive integrated circuit containing a Josephson junction on a substrate. Superconductive integrated circuits (or devices) using a Josephson junction are examples of superconductive quantum circuits (or devices), since the Josephson effect is based on a quantum mechanical tunneling process.

For example, the methods may be used to implement quantum computing devices. However, the disclosure is not limited to methods of manufacturing quantum computing devices. Rather, the disclosure basically covers all methods of manufacturing superconductive integrated circuitry containing a Josephson junction, e.g., a superconductive Josephson junction quantum circuit.

In some examples, the superconductive integrated circuit may, e.g., comprise or be a resonating circuit. A resonating circuit typically comprises (at least) a capacitor and an inductor. The resonating circuit can be a linear resonating circuit (e.g., harmonic oscillator) or a nonlinear resonating circuit (e.g., anharmonic oscillator). In quantum devices such resonating circuits are also referred to as quantum oscillators (QO).

A known technique which is, e.g., used in quantum computing is to use a Josephson junction to make a resonating circuit nonlinear (or, differently stated, the oscillator potential anharmonic). In quantum computing devices, quantum anharmonic oscillators are used to “form” qubits. Differently put, a nonlinear resonating circuit may “form” (or operate) a qubit. Qubits created by one or more (nonlinear) Josephson junctions in a (thus nonlinear) resonating circuit are sometimes also referred to as “Josephson qubits” in the art.

Other examples of superconductive Josephson junction quantum circuits are Josephson parametric amplifiers or traveling wave parametric amplifiers (TWPAs). These devices offer high gain and quantum-limited noise. For example, to build a large-scale multi-qubit quantum processor, qubit readout by multiplexing is desirable, which requires amplifiers with a large bandwidth, high gain and low added noise. Such a capability is provided by traveling-wave parametric amplifiers (TWPAs).

Other examples of electronic devices including a superconductive integrated circuit are single flux quantum (SFQ) devices. Such devices are transistor-like devices in which voltage pulses produced by Josephson junctions in the superconducting electronic (quantum) circuit (instead of the voltage levels produced by transistors in semiconductor electronics) are used to encode, process, and transport digital information. A superconductive integrated circuit containing a plurality of SFQ devices allows the formation of (R)SFQ ((rapid) single flux quantum) logic.

Referring to FIG. 1, a substrate 110 is provided. The substrate 110 may, e.g., comprise or be a sapphire substrate or a silicon substrate. In some implementations, the substrate 110 may comprise or be a high-resistive crystalline silicon substrate. The substrate 110 serves as a carrier for a superconductive integrated circuit to be built thereon. The substrate 110 may, e.g., be unstructured or unprocessed. In some implementations, no integrated circuits or integrated devices are formed in the substrate 110, for example.

A first superconductive layer 120 of a superconductive material is formed over the substrate 110. The first superconductive layer may be an unstructured, continuous layer which may, e.g., be deposited on the entire substrate 110.

The first superconductive layer 120 may be deposited by using a CVD (chemical vapor deposition) or PVD (physical vapor deposition) process. For example, the first superconductive layer 120 may be deposited by sputtering. The superconductive material is a material which can become superconductive at the operating temperature of the superconductive integrated circuit to be formed. Hence, the term “superconductive” refers to the state of conductivity of the material at operating temperature of the circuit. The superconductive material may, e.g., comprise or be of Al, Nb or Ta.

The first superconductive layer 120 may then be structured to form a structured first superconductive layer (which is also referred to by reference numeral 120). The structured first superconductive 120 layer includes structures 120_1, 120_2, 120_3 of the superconductive material. The structures 120_1, 120_2, 120_3 may, e.g., be electrically and/or structurally disconnected from each other.

For example, structuring the first superconductive layer 120 may be carried out by a patterning process using, e.g., a photolithographic mask, a photoresist (not shown) and an etching process. Other structuring processes, which may be compatible with semiconductor manufacturing, may also be used.

Subsequently, a first dielectric base layer 130 may be formed over the structured first superconductive layer 120. The first dielectric base layer 130 may be a continuous, unstructured layer of a dielectric material. The first dielectric base layer 130 may cover the entire substrate 110. The dielectric material may, e.g., comprise or be of silicon oxide or silicon nitride or a combination (oxynitride) of these materials.

The first dielectric base layer 130 may then be structured to form exposed regions 122_2, 122_3 of the structured first superconductive layer 120 (or, more specifically, of the structures 120_2, 120_3 of the structured first superconductive layer 120). The structured first dielectric base layer 130 may partly or fully cover areas of the substrate 110 in which the superconductive material of the first superconductive layer 120 has been removed. Further, the structured first dielectric base layer 130 may partly cover at least some of the structures 120_1, 120_2, 120_3 of the structured first superconductive layer 120.

Structuring of the first dielectric base layer 130 may be carried out by patterning processes (lithography and etching, for example) as mentioned above in connection of structuring the first superconductive layer 120. In other words, at selected areas of the structures 122_2, 122_3 of the structured first conductive layer 120, the first dielectric base layer 130 is opened so that at least a part of the structures 122_2, 122_3 is exposed.

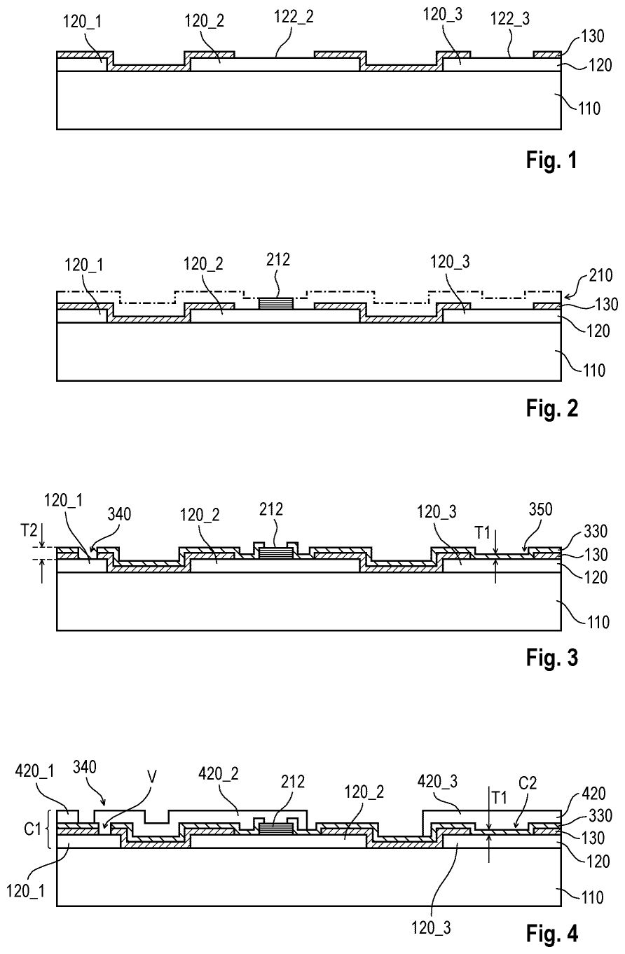

Referring to FIG. 2, a Josephson junction (JJ) layer stack 210 is formed over the first superconductive layer 120 (which, in this implementation, is already structured into disconnected structures 120_1, 120_2, 120_3). The JJ layer stack 210 may be a continuous, unstructured layer stack which is shown by the dash-dotted line in FIG. 2. The JJ layer stack 210 may cover the entire substrate 110, for example.

The JJ layer stack 210 includes a JJ barrier layer (not shown). The JJ barrier layer is the functional layer of the JJ layer stack 210 which provides JJ tunneling.

For example, the JJ layer stack 210 may, e.g., comprise or be a three layer stack of a superconducting/tunnel barrier/superconducting material. Possible three layers include, but are not limited to, Al/AlOx/Al, Nb/AlOx/Nb, or Ta/AlOx/Ta layer stacks. For example, other barrier layers than AlOx may be used (such as, e.g., MgOx, etc.), and also different combinations of superconducting materials may be used.

The JJ layer stack 210 may be deposited by sputtering or any other suitable deposition process. In the implementation illustrated in FIGS. 1 to 5, the JJ layer stack 210 may have a topography (e.g., is non-planar) due to the previous structuring process(es).

Still referring to FIG. 2, the JJ layer stack 210 is then structured to form a JJ structure 212. In some implementations, the parts of the JJ layer stack 210 overlaying (overlapping) the structured first dielectric base layer 130 may be completely removed.

Structuring of the JJ layer stack 210 may include etching processes. For example, reactive ion etching (RIE) may be used for metal and dielectric etching of the JJ layer stack 210 to form the JJ structure 212. RIE is anisotropic and therefore suitable to form the JJ structure 212 with (approximately) vertical side walls. As shown in FIG. 2, the JJ structure 212 is electrically contacted at its bottom to a structure 120_2 of the structured first superconductive layer 120.

Referring to FIG. 3, a dielectric cover layer 330 is then formed over the JJ structure 212. The dielectric cover layer 330 may be an unstructured, continuous layer, which may, e.g., cover the entire substrate 110. The dielectric cover layer 330 may comprise or be of one of the dielectric materials mentioned above in connection with the first dielectric base layer 130. The dielectric material of the dielectric cover layer 330 and the dielectric material of the first dielectric base layer 130 may be the same dielectric materials. In other examples, the dielectric material of the dielectric cover layer 330 and the dielectric material of the first dielectric base layer 130 may be different dielectric materials (and thus can be selectively structured).

Still referring to FIG. 3, the dielectric cover layer 330 is then structured a first time to expose an upper side of the JJ structure 212. In other words, the dielectric cover layer 330 is opened on top of the JJ structure 212.

Further, the dielectric cover layer 330 and the first dielectric base layer 130 may be opened at one or more selected location(s) 340 over one or more structures 120_1, 120_2, 120_3 of the (structured) first superconductive layer 120. In the example of FIG. 3, one selected location 340, at which the dielectric cover layer 330 and the first dielectric base layer 130 are opened, is shown over the structure 120_1. In other examples (not shown) an opening may be created at locations where only the dielectric cover layer 330 or only the first dielectric base layer 130 is present.

The resulting structure may contain areas on the structured first superconductive layer 120 with no dielectrics on top (here, the structure 120_1 at location 340), areas covered by dielectrics with a thickness T1 determined by the dielectric cover layer 330 as shown, e.g., at selected location 350 over structure 120_3, and areas with thicker dielectrics on top as formed, e.g., by the dielectric cover layer 330 and the first dielectric base layer 130 having a total thickness T2 (with T2>T1).

As will be described further below in more detail, the opening at selected location 340 may be used for contact formation (e.g., pad formation), the areas of dielectrics with a thickness T1 may be used for formation of capacitors with a high areal capacitance and the dielectrics areas with a thickness T2 may be used for the formation of capacitors with lower areal capacitance. In other words, the combination of the first dielectric base layer 130 and the dielectric cover layer 330 provides the option to have different areal capacitances. This offers flexibility in the design of the superconductive integrated circuit. In particular, TWPAs may use capacitors of different capacitance in the superconductive integrated circuit.

Referring to FIG. 4 a second superconductive layer 420 of a superconductive material is formed over the dielectric cover layer 330. The material of the second superconductive layer 420 may comprise or be of one or more of the materials mentioned above for the first superconductive layer 120. The superconductive material of the first superconductive layer 120 and the superconductive material of the second superconductive layer 420 may, e.g., be identical or different.

The second superconductive layer 420 is structured to form a structured second superconductive layer (also referred to by reference numeral 420 in the following). For example, by structuring the second superconductive layer 420, structures 420_1, 420_2 and 420_3 are provided. The structures 420_1, 420_2 and 420_3 may, e.g., be structurally disconnected and/or electrically disconnected with each other.

A part of the structured second superconductive layer 420, in this example structure 420_1, may be arranged opposite to structure 120_1 of the structured first superconductive layer 120, with the first dielectric base layer 130 and the dielectric cover layer 330 disposed in between. Since the thickness T2 may be chosen to be relatively large, this arrangement may form a capacitor C1 of low areal capacitance.

Another part of the structured second superconductive layer 420, in this example structure 420_2, may form a contact to the top of the JJ structure 212. In other words, the structure 120_2 of the structured first superconductive layer 120 and the structure 420_2 of the structured second superconductive layer 420 may be used to contact the JJ structure 212 at the bottom and the top side, respectively.

The structure 420_2 may, e.g., be further connected to the structure 120_1 of the structured first superconductive layer 120. For example, the structure 420_1 of the structured second superconductive layer 420 may overlay and fill the opening at selected location 340 in the first dielectric base layer 130 and the dielectric cover layer 330. That way, a via V connecting a part of the structured first superconductive layer 120 (e.g., structure 120_1) and a part of the structured second superconductive layer 420 (e.g., structure 420_2) is formed.

A superconductive integrated circuit on the substrate 110 may include or consist of the JJ structure 212, the via V and the capacitor C1. As described above, the implementation of such superconductive integrated circuit uses integration schemes that allow the formation of superconductive circuits including a JJ structure (e.g., three layer JJ structure) 212 with processes compatible with semiconductor manufacturing, that are scalable.

Further, at selected location 350, a part of the structured second superconductive layer (e.g., structure 420_3) may be arranged opposite to a part of the structured first superconductive layer 120 (e.g., structure 120_3), with the dielectric cover layer 330 of thickness T1 disposed in between. This arrangement may form a capacitor C2 of high areal capacitance (C2>C1). The capacitance C2 of capacitor C2 depends on the thickness T1 and the lateral size of the capacitor C2.

For example, the capacitance C2 may, e.g., be in the pF regime, for example in a range between 1 pF and 100 pF, more specifically 10 pF and 50 pF. The capacitance of capacitor C1 may, e.g., be in the 10 fF regime, for example in a range between 5 fF and 500 fF, more specifically 10 fF and 100 fF.

The capacitor C2 may, e.g., be electrically connected to (and thus may form a part of) the superconductive integrated circuit. In one example, the structure 120_2 of the structured first superconductive layer 120 may be connected by a wire (not shown) to the structure 420_3 of the second superconductive layer 420. In other examples, the structures 120_2 and 120_3 may, e.g., be continuous (e.g., connected with each other) so that one structure (corresponding to structures 120_2 and 120_3) of the structured first dielectric base layer 130 may simultaneously form a contact for the JJ structure 212 and a plate of the capacitor C2.

Subsequently, the entire arrangement (substrate 110 with structured superconductive layers 120, 420 and dielectric layer(s) 130 and 330) may be encapsulated by a passivation layer (not shown). In other examples, no passivation layer is applied.

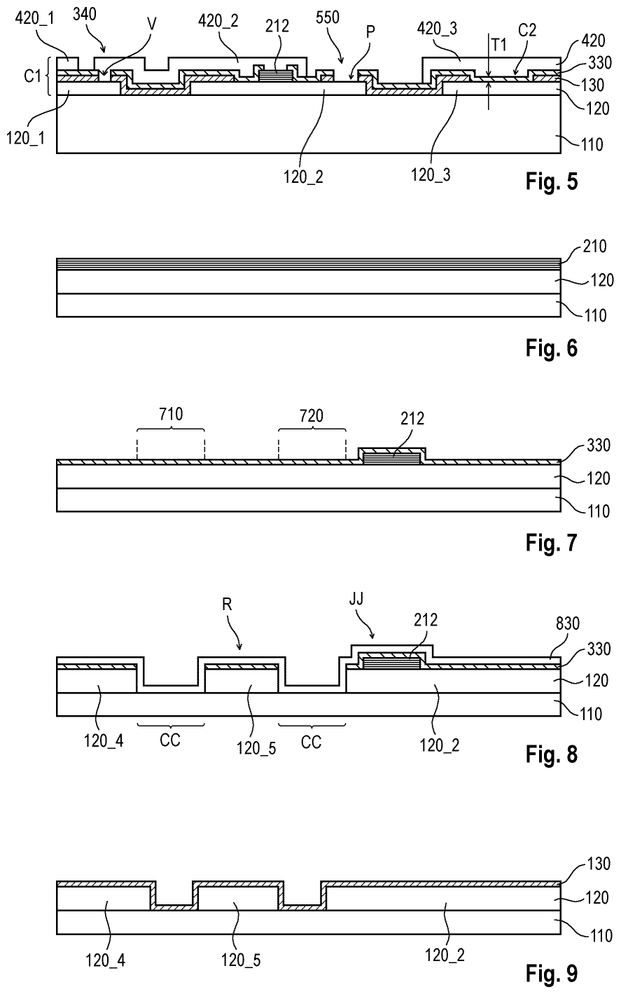

Referring to FIG. 5, the dielectric cover layer 330 may be structured at selected location 550 a second time. Structuring the dielectric cover layer 330 a second time is carried out after the second superconductive layer 420 has been structured. As shown in FIG. 5, simultaneously with opening the dielectric cover layer 330, the first dielectric base layer 130 may be opened. That way, a contact pad area of a contact pad P may be defined. The contact pad P allows to provide electrical contact to external circuitry (not shown).

The superconductive integrated circuit may include further contact pads P. For example, the structure 120_1 and/or the structure 120_3 of the structured first superconductive layer 120 may, e.g., also be connectable by similar contact pads (not shown) at other selected locations.

In the implementation exemplarily illustrated by FIGS. 1 to 5, the first dielectric base layer 130 is formed before the JJ layer stack 210 is formed over the structured first superconductive layer 120. In other implementations, the first dielectric base layer 130 may be formed after the JJ layer stack 210 is formed over the first superconductive layer 120, for example.

In this respect, referring to FIGS. 6 to 8 illustrating example stages of a second implementation of manufacturing a superconductive integrated circuit, the first superconductive layer 120 of superconductive material is formed over the substrate 110 as described, e.g., in connection with FIG. 1.

Subsequently, the JJ layer stack 210 including a JJ barrier layer is formed over the first superconductive layer 120. Reference is made to the above description to avoid reiteration.

In the second implementation the JJ layer stack 210 may be deposited on the unstructured first superconductive layer 120. The deposition of the first superconductive layer 120 and the JJ layer stack 210 may be carried out in one process step. For example, no intermediate processes such as, e.g., structuring of the first superconductive layer 120 and/or depositing any dielectric layer on the first superconductive layer 120 and/or structuring any such deposited dielectric layer need to be carried out before the JJ layer stack 210 is structured. The JJ layer stack 210 may be planar.

Referring to FIG. 7, the JJ layer stack 210 may be structured to generate the JJ structure 212 before the first superconductive layer 120 is structured. The JJ structure 212 may be formed out of the JJ layer stack 210 by structuring the JJ layer stack 210 through etching as described above, e.g., down to the tunnel barrier in the JJ layer stack 210.

Subsequently, the dielectric cover layer 330 may be formed over the JJ structure 212.

Subsequently, the first superconductive layer 120 is structured. Structuring the first superconductive layer 120 may, e.g., be carried out by opening the dielectric cover layer 330 at selected locations 710 and 720. In other words, the structured dielectric cover layer 330 may be used as a mask layer for structuring the first superconductive layer 120 using, e.g., an etching process. That way, structures 1202, 120_4 and 120_5 of the first superconductive layer 120 may be formed.

Subsequently, another cover layer 830 of a dielectric material is formed over the structured cover layer 330, the JJ structure 212 and the substrate 110, see FIG. 8.

The following manufacturing processes of the second implementation may, e.g., be similar or identical with processes described above in connection with FIGS. 3 to 5, and reference is made to the above description to avoid reiteration. Briefly, similar as shown in FIG. 3, the cover layers 330, 830 may be opened over the JJ structure 212 and, optionally, over other parts of the structured first superconductive layer 120. For example, similar as shown in FIG. 5 at selected location 550, the cover layers 330, 830 may be opened over structure 120_4 to provide a pad on structure 120_4.

Structure 120_5 may, e.g., used to implement a resonator R which is capacitively coupled (reference sign CC) to structure 1204 (which may be provided with a contact pad). In this example capacitive coupling CC is obtained in the lateral dimension, e.g., structure 120_4 and structure 1205 may form a lateral capacitor. The capacitance of this lateral capacitor depends, inter alia, on the distance between structure 120_4 and structure 120_5, e.g., the lateral dimension of selected location 710.

Structure 1205 (which may form a resonator R) may be coupled to structure 120_2 carrying the JJ structure 212 also by lateral capacitive coupling CC. In other examples, structure 120_5 may be connected to the second superconductive layer 420 (see FIG. 4) the same way as described and illustrated in connection with the first implementation (FIGS. 1 to 5). In other words, referring to the second implementation illustrated in FIGS. 6 to 8, the steps of structuring the cover layers 330, 830, of applying the second superconductive layer 420, of structuring the second superconductive layer 420 (see FIG. 4) and, optionally, of opening the cover layers 330, 830 at selected locations 550 (see FIG. 5) may be carried out the same way as described above.

Referring to FIGS. 9 to 18, a third implementation of a method of manufacturing a superconductive integrated circuit on a substrate 110 is described.

In this implementation, a first superconductive layer 120 of a superconductive material is formed over the substrate 110. As mentioned before, the first superconductive layer 120 may be a continuous, unstructured layer.

Similar as already described in connection with FIG. 1, the first superconductive layer 120 is structured to form a structured first superconductive layer 120. For example, structures 120_2, 120_4 and 120_5, as illustrated in FIG. 8, may be formed.

Subsequently, a first dielectric base layer 130 is formed over the structured first superconductive layer 120. In this respect, reference is made to the description in connection with FIG. 1 to avoid reiteration. The material of the first dielectric base layer 130 may be any of the aforementioned hard passivation materials, e.g., silicon nitride.

Subsequently, a second dielectric base layer (not shown) is formed over the first dielectric base layer 130. The dielectric material of the second dielectric base layer may be different from the dielectric material of the first dielectric base layer 130. As an example, the dielectric material of the first dielectric base layer 130 may, e.g., be silicon nitride and the material of the second dielectric base layer may, e.g., be silicon oxide.

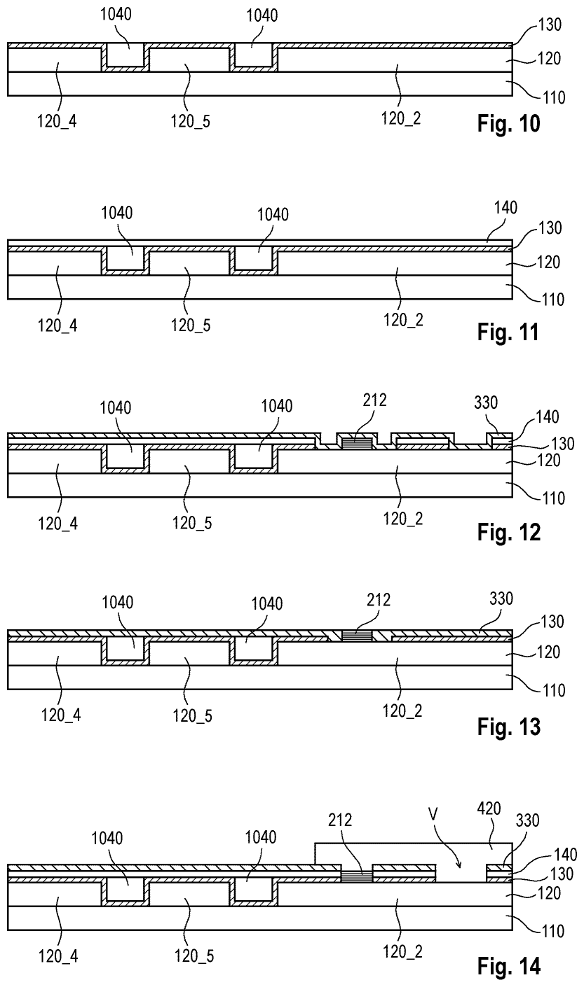

The second dielectric base layer may then be thinned (e.g., polished back by chemical mechanical polishing (CMP)) selectively to the first dielectric base layer 130. In the areas where the superconductive material of the structured first superconductive layer 120 is remaining (e.g., structures 120_2, 120_4, 120_5), the first dielectric base layer 130 is exposed, while the spaces in between may be filled by plugs 1040 of the dielectric material of the second dielectric base layer (see FIG. 10).

Subsequently, a third dielectric base layer 140 may be formed over the first dielectric base layer 130 and the plugs 1040 structured out of the second dielectric base layer. The material of the third dielectric base layer 140 may, e.g., be the same dielectric material as the material of the first dielectric base layer 130. In some examples, a low loss dielectric material such as, e.g., silicon nitride is used.

The third dielectric base layer 140 may be an unstructured, continuous layer which may, e.g., cover the entire surface of the arrangement shown in FIG. 11.

Subsequently, the first dielectric base layer 130 and the third dielectric base layer 140 (which may be of the same material) may be structured as described in connection with FIG. 1. That way, exposed regions of the structured first superconductive layer 120 may be formed (compare exposed regions 122_2 and 122_3 of FIG. 1).

Subsequently, a JJ layer stack including a JJ barrier layer (compare FIG. 2, reference sign 210) is formed over the first superconductive layer 120 (which is, in this implementation, already structured. The JJ layer stack (FIG. 2, reference sign 210) is then structured to form the JJ structure 212.

Subsequently, a dielectric cover layer 330 may be formed over the arrangement as shown in FIG. 12. The dielectric cover layer 330 covers the JJ structure 212.

The dielectric cover layer 330 may then be opened a first time to expose an upper side of the JJ structure 212, as illustrated and described in connection with FIG. 3. Opening the dielectric cover layer 330 on top of the JJ structure 212 may be carried out by a dedicated via etch process, e.g., by using RIE.

Alternatively, as illustrated in FIG. 13, the dielectric cover layer 330 may have a thickness equal to or greater than the thickness of the JJ structure 212. In this case the (thick) dielectric cover layer 330 may be thinned (e.g., polish back by CMP) until the top of the JJ structure 212 is exposed, see FIG. 13. For example, the third dielectric base layer 140 may be omitted in this process.

The following processes may be carried out in any of the implementations described before. Partly, they have already been described in these implementations, and reference is made to the description above to avoid reiteration.

Referring to FIG. 14, a second superconductive layer 420 of a superconductive material is formed over the dielectric cover layer 330. Previously, the dielectric layer(s) between the structured first superconductive layer 120 and the second superconductive layer 420 may be opened to form a via contact V to the structured first superconductive layer 120 (e.g., the structure 120_2 thereof). The second superconductive layer 420 may then be structured to form a structured second superconductive layer 420. For example, a region of the second superconductive layer 420 overlapping the dielectric plugs 1040, may be removed.

Optionally, the dielectric plugs 1040 may then be removed to reduce the amount of loss in the dielectric layer structure (comprising, e.g., of the first dielectric base layer 130, the dielectric cover layer 330 and, optionally, the third dielectric base layer 140). This may be done by forming holes in the low loss dielectric layer(s) 330, 140 above the dielectric plugs 1040 and by selectively removing the dielectric material of the dielectric plugs 1040 through these holes (FIG. 15).

Further to FIG. 15, the dielectric cover layer 330 and, e.g., other low loss dielectric layers such as, e.g., the first dielectric base layer 130 and optionally the third dielectric base layer 140, may be opened a second time to form a pad P of the superconductive integrated circuit on, e.g., the structure 120_4 of the structured first superconductive layer 120.

As described in connection with the second implementation (FIGS. 6 to 8), the structure 120_5 may form a resonator R which is capacitively coupled (CC) to structure 120_4 and, optionally, structure 120_2 of the structured first superconductive layer 120. In FIG. 15 the reference sign LLD refers to low loss dielectric layers which may, e.g., be implemented by dielectric layers 130, 330 and optionally 140 as described above.

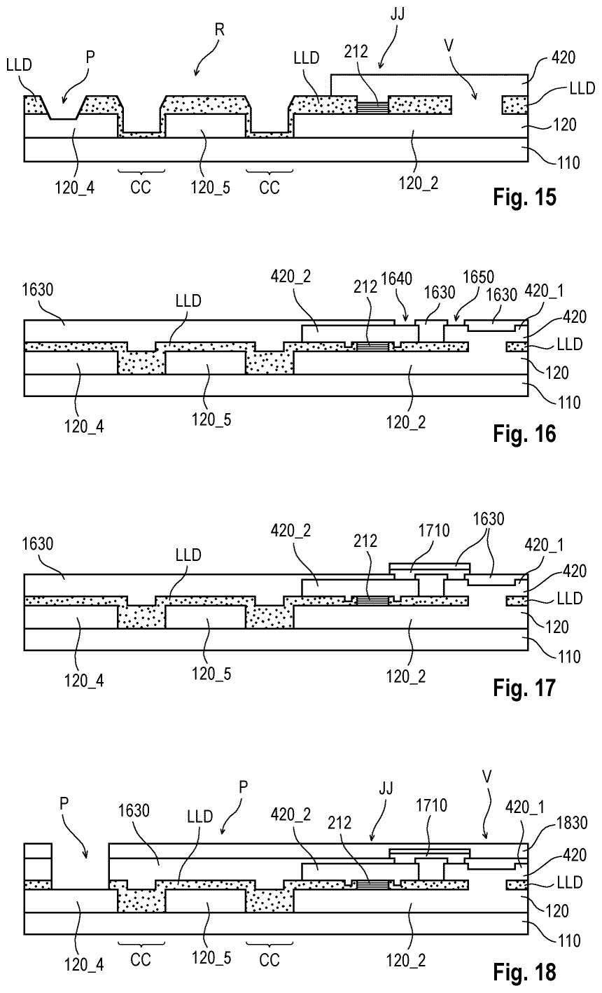

Referring to FIG. 16, before contact pad opening of the low loss dielectric layer(s) at P, a protective dielectric layer 1630 may be formed. The protective dielectric layer 1630 may, e.g., be a continuous, unstructured layer which may cover the entire arrangement. The protective dielectric layer 1630 (which has already been mentioned before) may cover the low loss dielectric layer LLD and the structured second superconductive layer 420. The protective dielectric layer 1630 may be of any of the aforementioned dielectric materials, in particular of a low loss dielectric material such as, e.g., silicon nitride.

In some examples, the protective dielectric layer 1630 may be planarized by, e.g., CMP. The planarized protective dielectric layer 1630 may then be used as a carrier for stacking to generate stacked superconducting integrated circuits, and process sequences as described above can be repeated. This allows, for example, a multi-level integration of JJ structures 212 and other superconducting circuit elements above the arrangement shown in FIG. 16.

In some examples, a resistive element 1710 (see FIG. 17) may be integrated in the superconductive integrated circuit. One possible method of integrating a resistive element is described in connection with FIG. 16. After planarization of the protective dielectric layer 1630, the protective dielectric layer 1630 may be opened at selected locations 1640, 1650 over the structured second superconductive layer 420 (e.g., over structure 420_2 and structure 420_1 thereof).

Subsequently, a metal layer that remains resistive at (cryogenic) operation temperatures may be deposited and structured in such a way that a resistive element 1710 with the desired resistance is created. The material of the resistive element 1710 (and thus of the metal layer of which the resistive element 1710 is structured) may, e.g., comprise or be of copper. The resistive element 1710 may contact the structure 420_2 and the structure 420_1 of the structured second superconductive 420 through the openings at selected locations 1640 and 1650, respectively. The integration of a resistive element 1710 allows the formation of a superconductive integrated circuit containing (R)SFQ logic, for example.

Referring to FIG. 18, subsequently, a further protective dielectric layer 1830 may be formed over the arrangement shown in FIG. 17, for example.

Subsequently, the dielectric layers (e.g., low loss dielectric layer LLD and, optionally, protective dielectric layers 1630, 1830) may be opened for contact pad P formation over a part (e.g., structure 120_4) of the structured first superconductive layer 120.

### Aspects

The following aspects pertain to further aspects of the disclosure:

Aspect 1 is a method of manufacturing a superconductive integrated circuit on a substrate comprises forming a first superconductive layer of a superconductive material over the substrate. A Josephson junction (JJ) layer stack including a JJ barrier layer is formed over the first superconductive layer. The JJ layer stack is structured to form a JJ structure. The first superconductive layer is structured to form a structured first superconductive layer. A dielectric cover layer is formed over the JJ structure. The dielectric cover layer is structured a first time to expose an upper side of the JJ structure. A second superconductive layer of a superconductive material is formed over the dielectric cover layer. The second superconductive layer is structured to form a structured second superconductive layer.

In Aspect 2, the subject matter of Aspect 1 can in the first to third implementation optionally further include structuring the dielectric cover layer a second time after the second superconductive layer has been structured.

In Aspect 3, the subject matter of Aspect 1 or 2 can in the first to third implementation optionally include wherein the structured first superconductive layer provides a first superconductive structure, the structured second superconductive layer provides a second superconductive structure, and wherein the second superconductive structure connects to the JJ structure and to the first superconductive structure.

In Aspect 4, the subject matter of any of the preceding Aspects can in the first to third implementation optionally include wherein the structured first superconductive layer and the structured second superconductive layer are structured to form a vertical capacitor with a capacitor dielectric material comprising the dielectric cover layer.

In Aspect 5, the subject matter of any of the preceding Aspects can in the first to third implementation optionally include wherein a first dielectric base layer is formed over the structured first superconductive layer.

In Aspect 6, the subject matter of Aspect 5 can in the first to third implementation optionally further include structuring the first dielectric base layer to form exposed regions of the structured first superconductive layer; and forming the dielectric cover layer over the exposed regions.

In Aspect 7, the subject matter of Aspect 5 or 6 can in the first and third implementation optionally include wherein the first dielectric base layer is formed before the JJ layer stack is formed over the first superconductive layer.

In Aspect 8, the subject matter of Aspect 5 or 6 can in the second implementation optionally include wherein the first dielectric base layer is formed after the JJ layer stack is formed over the first superconductive layer.

In Aspect 9, the subject matter of Aspect 8 can in the second implementation include wherein structuring the JJ layer stack is carried out before the first superconductive layer is structured.

In Aspect 10, the subject matter of any of Aspects 5 to 9 can in the first to third implementation optionally include wherein the first dielectric base layer is structured in the same structuring process used to structure the dielectric cover layer.

In Aspect 11, the subject matter of any of Aspects 5 to 10 can in the third implementation optionally further include forming a second dielectric base layer over the first dielectric base layer, the dielectric material of the second dielectric base layer being different from the dielectric material of the first dielectric base layer; and thinning the second dielectric base layer to expose the first dielectric base layer in regions over structures of the structured first superconductive layer.

In Aspect 12, the subject matter of Aspect 11 can in the third implementation optionally include wherein forming the JJ layer stack and structuring the JJ layer stack is carried out after the second dielectric base layer has been formed.

In Aspect 13, the subject matter of Aspect 11 or 12 can in the third implementation optionally include wherein the dielectric cover layer is formed over the second dielectric base layer after thinning the second dielectric base layer.

In Aspect 14, the subject matter of any of the preceding Aspects can in the first to third implementation optionally include wherein the dielectric cover layer comprises silicon nitride.

Although specific implementations have been illustrated and described herein, it will be appreciated by those of ordinary skill in the art that a variety of alternate and/or equivalent implementations may be substituted for the specific implementations shown and described without departing from the scope of the present implementation. This application is intended to cover any adaptations or variations of the specific implementations discussed herein. Therefore, it is intended that this implementation be limited only by the claims and the equivalents thereof.

1. A method of manufacturing a superconductive integrated circuit on a substrate, the method comprising:
forming a first superconductive layer of a first superconductive material over the substrate;
forming a Josephson Junction JJ layer stack including a JJ barrier layer over the first superconductive layer;
structuring the JJ layer stack to form a JJ structure;
structuring the first superconductive layer to form a structured first superconductive layer;
forming a dielectric cover layer over the JJ structure;
structuring the dielectric cover layer a first time to expose an upper side of the JJ structure;
forming a second superconductive layer of a second superconductive material over the dielectric cover layer; and
structuring the second superconductive layer to form a structured second superconductive layer.

2. The method of claim 1, further comprising:
structuring the dielectric cover layer a second time after the second superconductive layer has been structured.

3. The method of claim 1, wherein the structured first superconductive layer provides a first superconductive structure,
wherein the structured second superconductive layer provides a second superconductive structure, and
wherein the second superconductive structure connects to the JJ structure and to the first superconductive structure.

4. The method of claim 1, wherein the structured first superconductive layer and the structured second superconductive layer are structured to form a vertical capacitor with a capacitor dielectric material comprising the dielectric cover layer.

5. The method of claim 1, wherein a first dielectric base layer is formed over the structured first superconductive layer.

6. The method of claim 5, further comprising:
structuring the first dielectric base layer to form exposed regions of the structured first superconductive layer; and
forming the dielectric cover layer over the exposed regions.

7. The method of claim 5, wherein the first dielectric base layer is formed before the JJ layer stack is formed over the first superconductive layer.

8. The method of claim 5, wherein the first dielectric base layer is formed after the JJ layer stack is formed over the first superconductive layer.

9. The method of claim 8, wherein structuring the JJ layer stack is carried out before the first superconductive layer is structured.

10. The method of claim 5, wherein the first dielectric base layer is structured in a same structuring process used to structure the dielectric cover layer.

11. The method of claim 5, further comprising:
forming a second dielectric base layer over the first dielectric base layer, a dielectric material of the second dielectric base layer being different from a dielectric material of the first dielectric base layer; and
thinning the second dielectric base layer to expose the first dielectric base layer in regions over structures of the structured first superconductive layer.

12. The method of claim 11, wherein forming the JJ layer stack and structuring the JJ layer stack are carried out after the second dielectric base layer has been formed.

13. The method of claim 11, wherein the dielectric cover layer is formed over the second dielectric base layer after thinning the second dielectric base layer.

14. The method of claim 1, wherein the dielectric cover layer comprises a silicon nitride.

15. The method of claim 1, wherein the first superconductive material and the second superconductive material comprise a same superconductive material.

16. A method of manufacturing a superconductive integrated circuit on a substrate, the method comprising:
depositing a first superconductive layer of a first superconductive material over the substrate;
structuring the first superconductive layer to form a structured first superconductive layer, the structured first superconductive layer including a plurality of structures of the first superconductive material, and the plurality of structures of the first superconductive material being electrically and/or structurally disconnected from each other;
forming a Josephson Junction (JJ) layer stack including a JJ barrier layer over the first superconductive layer, the JJ layer stack comprising a continuous, unstructured layer stack;
structuring the JJ layer stack to form a JJ structure;
forming a dielectric cover layer over the JJ structure;
structuring the dielectric cover layer a first time to expose an upper side of the JJ structure;
forming a second superconductive layer of a second superconductive material over the dielectric cover layer; and
structuring the second superconductive layer to form a structured second superconductive layer.

17. The method of claim 16, further comprising:
structuring the dielectric cover layer a second time after the second superconductive layer has been structured.

18. The method of claim 16, wherein the structured first superconductive layer provides a first superconductive structure,
wherein the structured second superconductive layer provides a second superconductive structure, and
wherein the second superconductive structure connects to the JJ structure and to the first superconductive structure.

19. The method of claim 16, wherein the structured first superconductive layer and the structured second superconductive layer are structured to form a vertical capacitor with a capacitor dielectric material comprising the dielectric cover layer.

20. The method of claim 16, wherein a first dielectric base layer is formed over the structured first superconductive layer, the method further comprising:
structuring the first dielectric base layer to form exposed regions of the structured first superconductive layer; and
forming the dielectric cover layer over the exposed regions.
